(19) United States
(12) Patent Application Publication
(10) Pub. No.: US 2024/0079396 A1
(43) Pub. Date: Mar. 7, 2024

(54) PACKAGE STRUCTURE USING SEMICONDUCTOR CHIP TO SEPARATE DIFFERENT POTENTIALS

(71) Applicant: Richtek Technology Corporation, Zhubei City (TW)

(72) Inventors: Lung-Sheng LIN, Taichung City (TW); Chih-Feng HUANG, Xinpu Township (TW); Ta-Yung YANG, Taoyuan City (TW)

(21) Appl. No.: 18/060,086

(22) Filed: Nov. 30, 2022

(30) Foreign Application Priority Data
Sep. 6, 2022 (TW) 111133726

(51) Int. Cl. H01L 25/16; H01L 23/495

(52) U.S. Cl. CPC H01L 25/16; H01L 23/49575

(57) ABSTRACT

A package structure includes a first carrier, a second carrier, and a first electronic device. The first carrier is electrically connected to a first voltage. The second carrier includes a first substrate and a first interconnect structure. The first substrate is in contact with the first carrier, the first interconnect structure is electrically connected to a second voltage, and the first interconnect structure and the first carrier are deposited on two opposite sides of the first substrate. The first electronic device is deposited on the first interconnect structure and away from the first carrier. The first electronic device is in contact with the first interconnect structure.

### CROSS REFERENCE TO RELATED APPLICATIONS

This Application claims priority of Taiwan Patent Application No. 111133726, filed on Sep. 6, 2022, the entirety of which is incorporated by reference herein.

### BACKGROUND OF THE INVENTION

### Field of the Invention

The present invention relates to a package structure using a semiconductor chip as a chip holder, and, in particular, to a package structure using the semiconductor chip to separate different potentials on the lead frame and to electrically connect the chips through the interconnect structure on the semiconductor substrate.

### Description of the Related Art

An Intelligent Power Module (IPM) is a high-performance and high-reliability packaging technology that integrates multiple power components (e.g., complementary metal-oxide semiconductor), gate-driving circuits, and passive components. Since the potentials of the carrier carrying the microprocessor, the gate-driving circuits, the power elements and the bootstrap diodes are different from one another, the lead frame must be divided into chip holders with different potentials. It is especially important that sufficient high-voltage spacing must be maintained between the chip holders with different potentials, or else problems may arise, such as an inability to reduce the area of the package and difficulty in making the lead frame. In addition, the chip holders of the power devices must be divided into small sizes, resulting in poor heat dissipation and complicated wiring between chips.

In order to overcome the various problems caused by dividing the lead frame, it is necessary to optimize the lead frame of the intelligent power module.

### BRIEF SUMMARY OF THE INVENTION

The package structure proposed by the present invention may avoid various problems caused by dividing the lead frame. To maintain the maximum lead frame, the chip holders having different voltages are provided. In addition to retaining the heat dissipation performance of the lead frame, the package area is reduced and the difficulty of manufacturing the lead frame is reduced. In addition, the package structure proposed by the present invention further provides an additional degree of freedom for routing, which greatly reduces the routing difficulty of bonding wires. Furthermore, various active components and passive components can be formed under the chip holders, and other external components may also be integrated around the chip holders, thereby improving the feasibility of a System in a Package (SiP).

In an embodiment, a package structure is provided, which comprises a first carrier, a second carrier, and a first electronic device. The first carrier is electrically connected to a first voltage. The second carrier comprises a first substrate and a first interconnect structure. The first substrate is in contact with the first carrier. The first interconnect structure is electrically connected to a second voltage. The first interconnect structure and the first carrier are located on two opposite sides of the first substrate. The first electronic device is deposited on the first interconnect structure and away from the first carrier. The first electronic device and the first interconnect structure are in contact with each other.

According to an embodiment of the invention, the second carrier further comprises a first insulating layer. The first insulating layer is deposited between the first substrate and the first interconnect structure. The thickness of the insulating layer is determined according to a voltage difference of the first voltage and the second voltage.

According to an embodiment of the invention, an electronic component is formed in the second carrier, and the electronic component comprises a resistance component or an inductance component.

According to an embodiment of the invention, a capacitance component is formed between the first interconnect structure and the first substrate.

According to an embodiment of the invention, the second carrier further comprises a second interconnect structure deposited on the first substrate. The second interconnect structure and the first carrier are located on two opposite sides of the first substrate, and the first interconnect structure and the second interconnect structure are electrically isolated from each other.

According to an embodiment of the invention, a first pad on the first electronic device is electrically connected to the second interconnect structure through a first metal wire. The package structure further comprises a third carrier and a second electronic device. The third carrier comprises a second substrate, a third interconnect structure, and a fourth interconnect structure. The second substrate is in contact with the first carrier. The third interconnect structure is electrically connected to a third voltage and formed on the second substrate, and the third interconnect structure and the first carrier are located on two opposite sides of the second substrate. The fourth interconnect structure is formed on the second substrate, and the fourth interconnect structure and the third interconnect structure are located on two opposite sides of the second substrate. The fourth interconnect structure and the third interconnect structure are electrically isolated from each other. The second electronic device is deposited on the third interconnect structure and in contact with the third interconnect structure. A second pad of the second electronic device is electrically connected to the first pad.

According to an embodiment of the invention, the second pad is electrically connected to the fourth interconnect structure through a second metal wire, and the fourth interconnect structure is electrically connected to the second interconnect structure through a third metal wire.

According to an embodiment of the invention, the second pad is electrically connected to the second interconnect structure through a second metal wire.

According to an embodiment of the invention, the third carrier further comprises a second insulating layer. The second insulating layer is deposited between the second substrate and the third interconnect structure and deposited between the second substrate and the fourth interconnect structure. The thickness of the second insulating layer is determined according to a voltage difference of the first voltage and the third voltage and/or a voltage difference of the first carrier and the fourth interconnect structure.

According to an embodiment of the invention, the first substrate and the second substrate are in contact with each other to form a third substrate, wherein the third substrate is a semiconductor substrate.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a top view of a package structure in accordance with an embodiment of the present invention;

FIG. 2 is a cross-sectional view of a package structure in accordance with an embodiment of the present invention;

FIG. 3 is a block diagram of a motor driving circuit in accordance with an embodiment of the present invention; and

FIG. 4 is a top view of the package structure of the motor driving circuit of FIG. 3 in accordance with the present invention.

### DETAILED DESCRIPTION OF THE INVENTION

The following description is made for the purpose of illustrating the general principles of the disclosure and should not be taken in a limiting sense. The scope of the disclosure is determined by reference to the appended claims.

In the following detailed description, for purposes of explanation, numerous specific details and embodiments are set forth in order to provide a thorough understanding of the present disclosure. The use of like and/or corresponding numerals in the drawings of different embodiments does not suggest any correlation between different embodiments.

In addition, in this specification, relative spatial expressions are used. For example, “lower”, “bottom”, “higher” or “top” are used to describe the position of one element relative to another. It should be appreciated that if a device is flipped upside down, an element that is “lower” will become an element that is “higher”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer or section. Thus, a first element, component, region, layer, portion or section in the specification could be termed a second element, component, region, layer, portion or section in the claims without departing from the teachings of the present disclosure.

It should be understood that this description of the exemplary embodiments is intended to be read in connection with the accompanying drawings, which are to be considered part of the entire written description. The drawings are not drawn to scale. In addition, structures and devices are shown schematically in order to simplify the drawing.

The terms “approximately”, “about” and “substantially” typically mean a value is within a range of +/−20% of the stated value, more typically a range of +/−10%, +/−5%, +/−3%, +/−2%, +/−1% or +/−0.5% of the stated value. The stated value of the present disclosure is an approximate value. Even there is no specific description, the stated value still includes the meaning of “approximately”, “about” or “substantially”.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

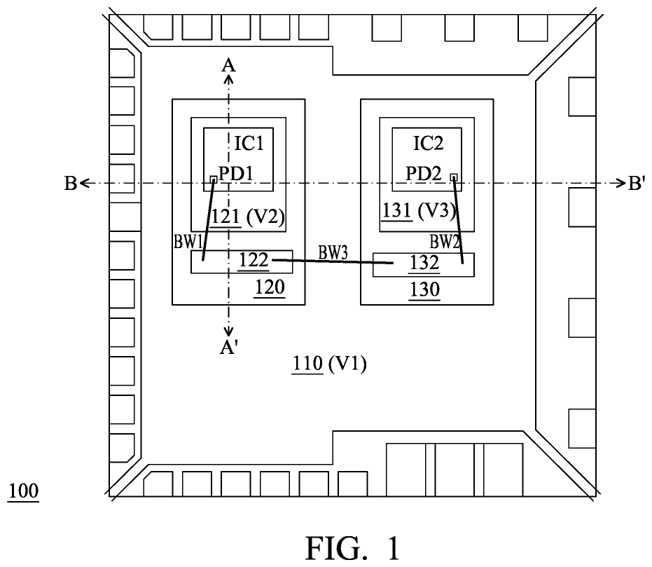

FIG. 1 is a top view of a package structure in accordance with an embodiment of the present invention. As shown in FIG. 1, the package structure 100 includes a first carrier 110, a second carrier 120, and a third carrier 130. The first carrier 110 is coupled to the first voltage V1. The second carrier 120 is disposed on the first carrier 110 and coupled to the second voltage V2. The third carrier 130 is disposed on the first carrier 110 and coupled to the third voltage V3. According to an embodiment of the present invention, the first voltage V1, the second voltage V2, and the third voltage V3 are different from one another. According to some embodiments of the present invention, the first carrier 110 is a lead frame.

As shown in FIG. 1, the second carrier 120 includes a first interconnect structure 121 and a second interconnect structure 122, where the first interconnect structure 121 and the second interconnect structure 122 are electrically isolated from each other. The third carrier 130 includes a third interconnection structure 131 and a fourth interconnection structure 132, where the third interconnection structure 131 and the fourth interconnection structure 132 are electrically isolated from each other.

As shown in FIG. 1, the package structure 100 further includes a first electronic device IC1 and a second electronic device IC2. The first electronic device IC1 is disposed on the first interconnect structure 121 and is in contact with the first interconnect structure 121. The second electronic device IC2 is disposed on the third interconnection structure 131 and is in contact with the third interconnection structure 131. According to an embodiment of the present invention, the first interconnecting structure 121 and the third interconnecting structure 131 are chip holders. According to some embodiments of the present invention, the first electronic device IC1 and the second electronic device IC2 may be an electronic component, where the electronic components include a resistor, an inductor, a capacitor, a transistor, and a diode.

The first electronic device IC1 includes a first pad PD1, and the first pad PD1 is electrically coupled to the second interconnect structure 122 through the first metal wire BW1. The second electronic device IC2 includes a second pad PD2, and the second pad PD2 is electrically coupled to the fourth interconnect structure 132 through the second metal wire BW2.

In addition, the second interconnect structure 122 is electrically coupled to the fourth interconnect structure 132 through the third metal wire BW3. According to some embodiments of the present invention, the first metal wire BW1, the second metal wire BW2, and the third metal wire BW3 are bonding wires in the package structure 100. In other words, the first pad PD1 is electrically coupled to the second pad PD2 through the bonding wires of the package structure 100 and the interconnection structures in the second carrier 120 and the third carrier 130.

According to another embodiment of the present invention, the first pad PD1 can also be electrically coupled to the fourth interconnect structure 132 through the bonding wire of the package structure 100, and then electrically coupled to the second pad PD2 through the bonding wire of the package structure 100. Since the bonding pad may be electrically coupled to another bonding pad through the bonding wire and the interconnecting structure in the carrier, the degree of freedom of electrical coupling within the package structure may be increased.

As shown in FIG. 1, the first electronic device IC1 and the second electronic device IC2 are respectively disposed on the second carrier 120 and the third carrier 130, and the second carrier 120 and the third carrier 130 both are disposed on the first carrier 110 and are electrically isolated from the first carrier 110, so the heat generated by the first electronic device IC1 and the second electronic device IC2 during operation may pass through the second carrier 120 and third carrier 130 respectively to the first carrier 110 for heat dissipation. Compared with the split lead frame method, maintaining the integrity of the first carrier 110 helps to improve the heat dissipation efficiency.

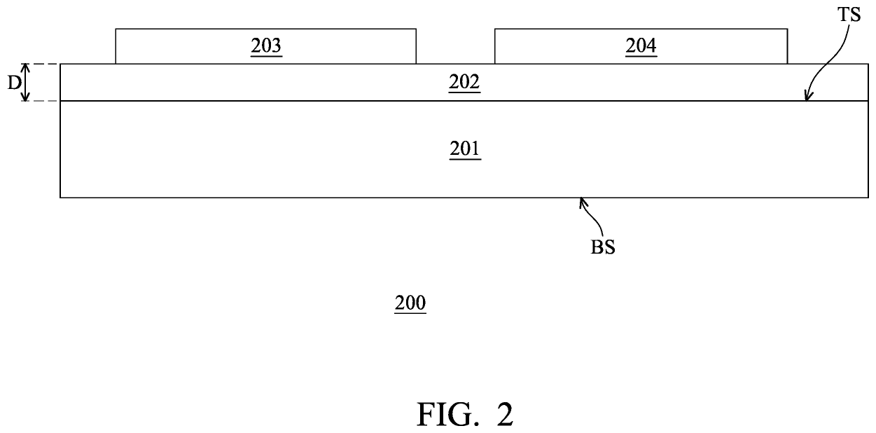

FIG. 2 is a cross-sectional view of a package structure in accordance with an embodiment of the present invention. As shown in FIG. 2, the carrier 200 includes a substrate 201, where the substrate 201 includes a bottom surface BS and a top surface TS. According to some embodiments of the present invention, the substrate 201 is a semiconductor substrate. The substrate 201 may include silicon, or the substrate 201 may include other elemental semiconductors, or compound semiconductors, such as silicon carbide, gallium arsenic, indium arsenide, and indium phosphide. The substrate 201 may include alloy semiconductors such as silicon germanium, silicon germanium carbide, gallium arsenic phosphide, and gallium indium phosphide.

In some embodiments, the substrate 201 includes an epitaxial layer, e.g., the substrate 201 has an epitaxial layer on a bulk semiconductor material. Furthermore, the substrate 201 may include a semiconductor-on-insulator (SOI) structure. For example, the substrate 201 may include a buried oxide (BOX) layer formed by, for example, separation by implanted oxide (SIMOX) or other suitable techniques such as wafer bonding and grinding process.

The carrier 200 includes an insulating layer 202, a first interconnect structure 203 and a second interconnect structure 204. The insulating layer 202 has a thickness D. The insulating layer 202 is disposed on the top surface TS of the substrate 201 and is in contact with the top surface TS. The first interconnect structure 203 and the second interconnect structure 204 are disposed on the insulating layer 202 and away from the top surface TS, and the first interconnect structure 203 and the second interconnect structure 204 are electrically separated from each other. According to an embodiment of the present invention, the first interconnecting structure 203 and the second interconnecting structure 204 are composed of metal.

As in the embodiment shown in FIG. 2, both the first interconnect structure 203 and the second interconnect structure 204 are in contact with the insulating layer 202. According to another embodiment of the present invention, the first interconnect structure 203 and the second interconnect structure 204 may be stacked, and the first interconnect structure 203 and the second interconnect structure 204 have additional insulating layers. For example, the second interconnection structure 204 and the insulating layer 202 are in contact with each other, the first interconnection structure 203 is formed on the second interconnection structure 204, and there is an insulating layer between the first interconnection structure 203 and the second interconnection structure 204. The embodiment shown in FIG. 2 is merely illustrated for explanation, but not intended to be limited thereto.

According to an embodiment of the present invention, the carrier plate 200 of FIG. 2 is cut along the line A-A′ in FIG. 1. Therefore, the carrier 200 corresponds to the second carrier 120 in FIG. 1, the bottom surface BS of the substrate 201 is in contact with the first carrier 110 in FIG. 1, and the first electronic device IC1 is disposed on the first interconnect structure 203 and in contact with the first interconnect structure 203. The substrate 201 is coupled to the first voltage V1, and the first interconnect structure 203 is coupled to the second voltage V2. According to an embodiment of the present invention, the thickness D of the insulating layer 202 is determined by the voltage difference between the first voltage V1 and the second voltage V2. According to other embodiments of the present invention, the carrier 200 also corresponds to the third carrier 130 in FIG. 1.

According to some embodiments of the present invention, electronic components may be formed in the carrier 200, where the electronic components include active components and passive components. According to an embodiment of the present invention, the first interconnect structure 203 and/or the second interconnect structure 204 or other additional interconnect structures may be used to form the inductor and the resistor. According to some embodiments of the present invention, a capacitive element may be formed between the first interconnect structure 203 and the substrate 201 (or between the second interconnect structure 204 and the substrate 201). According to another embodiment of the present invention, the capacitor and the resistor can be formed by using the oxide layer of the second carrier 200.

According to another embodiment of the present invention, the carrier plate 200 of FIG. 2 is cut along the line B-B′ in FIG. 1. Therefore, the first interconnect structure 203 corresponds to the second carrier 120 in FIG. 1, and the second interconnect structure 204 corresponds to the third carrier 130 in FIG. 1. In other words, the second carrier 120 and the third carrier 130 in FIG. 1 are formed on the same substrate 201 and insulating layer 202, and the thickness of the insulating layer 202 may be determined according to the voltage difference between the first interconnect structure 203 and the substrate 201 and the voltage difference between the second interconnect structure 204 and the substrate 201.

According to another embodiment of the present invention, the second carrier 120 and the third carrier 130 in FIG. 1 may also be formed on different substrates. According to other embodiments of the present invention, the carrier 200 may include other interconnect structures for wiring and forming electronic components. In the following embodiments, it will be explained that different carriers are formed on the same substrate, but it is not intended to be limited thereto.

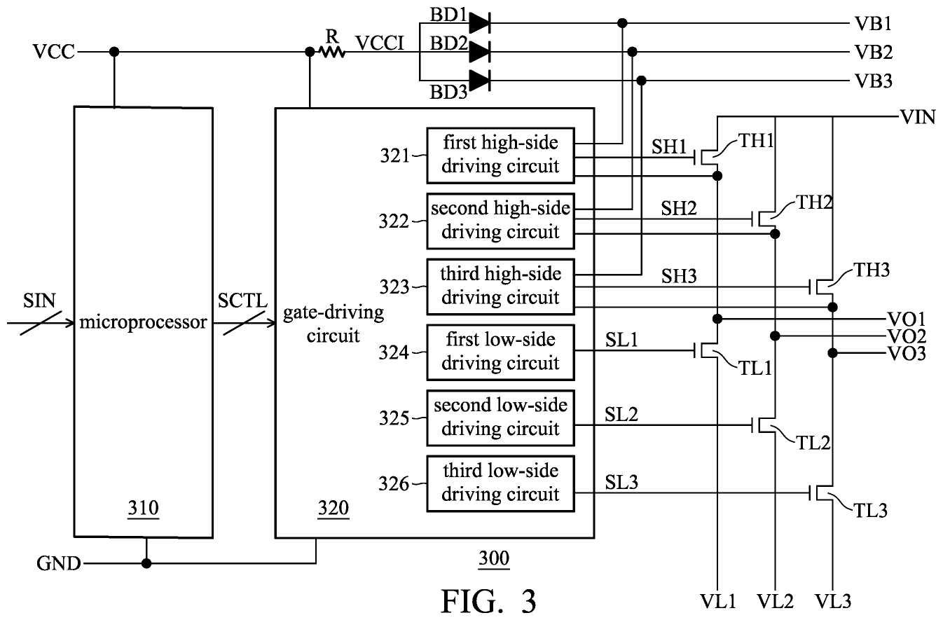

FIG. 3 is a block diagram of a motor driving circuit in accordance with an embodiment of the present invention. As shown in FIG. 3, the motor drive circuit 300 includes a microprocessor 310, a first bootstrap diode BD1, a second bootstrap diode BD2, a third bootstrap diode BD3, a resistor R, and a gate-driving circuit 320. The microprocessor 310 is powered by the supply voltage VCC and the ground terminal GND, and generates the control signal SCTL according to the input signal SIN.

The supply voltage VCC generates the internal supply voltage VCCI through the resistor R. The first bootstrap diode BD1, the second bootstrap diode BD2, and the third bootstrap diode BD3 boost the internal supply voltage VCCI to the first bootstrap voltage VB1, the second bootstrap voltage VB2, and the third bootstrap voltage VB3 respectively. The resistor R is configured to limit the currents from the supply voltage VCC to the first bootstrap diode BD1, the second bootstrap diode BD2, and the third bootstrap diode BD3. The gate-driving circuit 320 is powered by the supply voltage VCC and the ground GND, and includes a first high-side driving circuit 321, a second high-side driving circuit 322, a third high-side driving circuit 323, a first low-side driving circuit 324, the second low-side driving circuit 325, and the third low-side driving circuit 326.

According to the control signal SCTL, the gate-driving circuit 320 makes the first high-side driving circuit 321, the second high-side driving circuit 322, the third high-side driving circuit 323, the first low-side driving circuit 324, the second low-side driving circuit 325, and the third low-side driving circuit 326 respectively generate a first high-side driving signal SH1, a second high-side driving signal SH2, a third high-side driving signal SH3, a first low-side driving signal SL1, a second low-side driving signal SL2, and the third low-side driving signal SL3.

As shown in FIG. 3, the motor driving circuit 300 further includes a first high-side transistor TH1, a second high-side transistor TH2, a third high-side transistor TH3, a first low-side transistor TL1, a second high-side transistor TL2, and a third low-side transistor TL3. The first high-side transistor TH1, the second high-side transistor TH2, and the third high-side transistor TH3 output the input voltage VIN as a first output voltage VO1, a second output voltage VO2 and a third output voltage V03 respectively based on the first high-side driving signal SH1, the second high-side driving signal SH2, and the third high-side driving signal SH3.

The first high-side driving signal SH1 is located between the input voltage VIN and the first output voltage VO1 and configured to completely turn on and off the first high-side transistor TH1. The second high-side driving signal SH2 is located between the input voltage VIN and the second output voltage VO2 for completely turning on and off the second high-side transistor TH2. The third high-side driving signal SH3 is located between the input voltage VIN and the third output voltage V03 for completely turning on and off the third high-side transistor TH3.

The first low-side transistor TL1, the second low-side transistor TL2, and the third low-side transistor TL3 respectively pull down the first output voltage VO1, the second output voltage VO2 and the third output voltage V03 to the first low-side voltage VL1, the second low-side voltage VL2 and the third low-side voltage VL3 based on the first low-side driving signal SL1, the second low-side driving signal SL2 and the third low-side driving signal SL3.

Since the microprocessor 310, the gate-driving circuit 320, the first bootstrap diode BD1, the second bootstrap diode BD2, the third bootstrap diode BD3, the first high-side transistor TH1, the second high-side transistor TH2, the third high-side transistor TH3, the first low-side transistor TL1, the second low-side transistor TL2, and the third low-side transistor TL3 are respectively located in different chip holders having different voltages, the motor driving circuit 300 in FIG. 3 is illustrated for explain the package structure provided herein in the following paragraphs, but the present invention is not intended to be limited thereto.

However, in order to simplify the description, only the connection relationship among the gate-driving circuit 320, the first bootstrap diode BD1, the second bootstrap diode BD2, the third bootstrap diode BD3, and the first high-side transistor TH1, the second high-side transistor TH2, the third high-side transistor TH3, the first low-side transistor TL1, the second low-side transistor TL2, and the third low-side transistor TL3 will be explained in the following paragraphs.

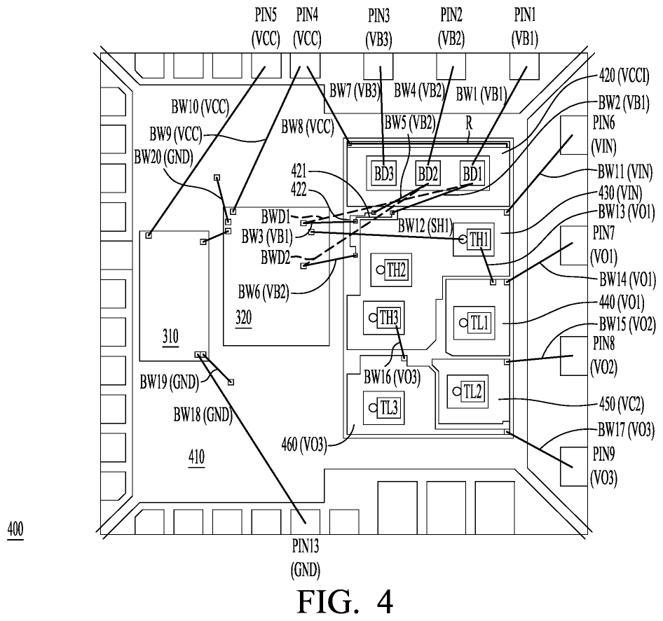

FIG. 4 is a top view of the package structure of the motor driving circuit in FIG. 3 in accordance with the present invention. In order to simplify the description below, the package structure 400 in FIG. 4 does not completely correspond to the motor driving circuit 300 in FIG. 3.

As shown in FIG. 4, the package structure 400 includes a first carrier 410, a second carrier 420, a third carrier 430, a fourth carrier 440, a fifth carrier 450, and a sixth carrier 460, The second carrier 420, the third carrier 430, the fourth carrier 440, the fifth carrier 450 and the sixth carrier 460 are all disposed on the first carrier 410. According to an embodiment of the present invention, the second carrier 420, the third carrier 430, the fourth carrier 440, the fifth carrier 450, and the sixth carrier 460 are different interconnect structures formed on the same substrate, which are electrically separated from one another.

As shown in FIG. 4, the microprocessor 310 and the gate-driving circuit 320 in FIG. 3 are disposed on the first carrier 410 and are in contact with the first carrier 410. The first bootstrap diode BD1, the second bootstrap diode BD2, and the third bootstrap diode BD3 are all disposed on the second carrier 420 and are in contact with the second carrier 420. The first bootstrap diode BD1 provides the first bootstrap voltage VB1 to the gate-driving circuit 320 through the first metal wire BW1, and provides the first bootstrap voltage VB1 to the first pin PIN1 through the second metal wire BW2, the first connection wire 421, and the third metal wire BW3.

The second bootstrap diode BD2 provides the second bootstrap voltage VB2 to the second pin PIN2 through the fourth metal wire BW4, and provides the second bootstrap voltage VB2 to the gate-driving circuit 320 through the fifth metal wire BW5, the second connection wire 422, and the sixth metal wire BW6. According to an embodiment of the present invention, the first connection line 421 and the second connection line 422 are connected to the second carrier 420, the third carrier 430, the fourth carrier 440, the fifth carrier 450 and the sixth carrier 460 is formed by other interconnect structures that are different and located on the same substrate. In other words, the first connection line 421 and the second connection line 422 are formed by the interconnect structures on the same substrate other than the second carrier 420, the third carrier 430, the fourth carrier 440, the fifth carrier 450 and the sixth carrier 460. In other words, the first connection line 421 and the second connection line 422 are electrically separated from the second carrier 420, the third carrier 430, the fourth carrier 440, the fifth carrier 450, and the sixth carrier 460, and the first connection line 421, the second connection line 422, the second carrier 420, the third carrier 430, the fourth carrier 440, the fifth carrier 450, and the sixth carrier 460 are on the same substrate.

According to some embodiments of the present invention, when the first bootstrap diode BD1 and the second bootstrap diode BD2 are electrically connected to the gate-driving circuit 320 through the first dummy wire BWD1 and the second dummy wire BWD2 respectively as shown in FIG. 4, it can be seen that the first dummy wire BWD1 and the second dummy wire BWD2 may cross, which causes difficulty in routing. Therefore, the first connection wires 421 and the second connection wires 422 provide the flexibility of the internal wiring of the package structure 400.

The fourth pin PIN4 provides the second carrier 420 with the supply voltage VCC through the resistor R and the eighth metal wire BW8, where the resistor R is formed in the second carrier 420. According to an embodiment of the present invention, since the resistor R shown in FIG. 3 is formed in the second carrier 420 to integrate external components into the package, not only one external electronic component can be eliminated, but also the circuit area can be reduced. In addition, the fourth pin PIN4 provides the supply voltage VCC to the gate-driving circuit 320 through the ninth metal wire BW9, and the fifth pin PIN5 provides the supply voltage VCC to the microprocessor 310 through the tenth metal wire BW10.

The sixth pin PIN6 provides the input voltage VIN to the third carrier 430 through the eleventh metal wire BW11, and the first high-side transistor TH1, the second high-side transistor TH2 and the third high-side transistor TH3 are disposed on the third carrier 430 and in contact with the third carrier 430.

The first high-side transistor TH1 receives the first high-side driving signal SH1 from the gate-driving circuit 320 through the twelfth metal wire BW12, and provides the first output voltage VO1 to the fourth carrier 440 through the thirteenth metal wire BW13. The fourth carrier 440 provides the first output voltage VO1 to the seventh pin PIN7 through the fourteenth metal wire BW14.

The fifth carrier 450 provides the second output voltage VO2 to the eighth pin PIN8 through the seventeenth metal wire BW17. The third high-side transistor TH3 provides the third output voltage V03 to the sixth carrier 460 through the sixteenth metal wire BW16, and the sixth carrier 460 provides the third output voltage V03 to the ninth pin PIN9 through the seventeenth metal wire BW17.

The thirteenth pin PIN13 electrically connects the ground GND to the microprocessor 310 through the eighteenth metal wire BW18, and then electrically connects the ground GND to the first carrier 410 through the nineteenth metal wire BW19. In addition, the gate-driving circuit 320 is electrically coupled to the ground GND of the first carrier 410 through the twentieth metal wire BW20. According to some embodiments of the present invention, the metal wires BW1-BW20 are bonding wires in the package structure 400.

As shown in FIG. 4, the first bootstrap voltage VB1, the second bootstrap voltage VB2, the third bootstrap voltage VB3, the first low-side driving voltage SL1, and the second low-side driving voltage SL2 must cross other bonding wires to route. Through the interconnection structures on the substrate, the complexity of routing by only bonding wires can be significantly reduced. In addition, since the second carrier 420, the third carrier 430, the fourth carrier 440, the fifth carrier 450, and the sixth carrier 460 are all formed on the same substrate, it is possible to increase the thickness of the insulating layer between the carriers and the substrate to maintain sufficient high-voltage isolation distance. In other words, compared to that the horizontal spacing needs to be maintained to withstand high voltage for the split lead frame, and the vertical thicknesses of the insulating layer between the carriers and the substrate may be increased to withstand high voltage, so that the area of the package may be reduced. Furthermore, since the high-voltage components are all disposed on the substrate and the lead frame (i.e., the first carrier 410) is not divided, the difficulty of manufacturing the lead frame is reduced, and the heat dissipation capability is not reduced by dividing the lead frame.

The package structure proposed by the present invention may avoid various problems caused by dividing the lead frame. To maintain the maximum lead frame, chip holders having different voltages are provided. In addition to retaining the heat dissipation performance of the lead frame, the package area is reduced and the difficulty of manufacturing the lead frame is reduced. In addition, the package structure proposed by the present invention further provides an additional degree of freedom for routing, which greatly reduces the routing difficulty of bonding wires. Furthermore, various active components and passive components can be formed under the chip holders, and other external components may also be integrated around the chip holders, thereby improving the feasibility of a System in a Package (SiP).

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A package structure, comprising:
a first carrier, electrically connected to a first voltage;
a second carrier, comprising:
a first substrate, in contact with the first carrier; and
a first interconnect structure, electrically connected to a second voltage, wherein the first interconnect structure and the first carrier are located on two opposite sides of the first substrate; and
a first electronic device, deposited on the first interconnect structure and away from the first carrier, wherein the first electronic device and the first interconnect structure are in contact with each other.

2. The package structure as defined in claim 1, wherein the second carrier further comprises:
a first insulating layer, deposited between the first substrate and the first interconnect structure, wherein the thickness of the insulating layer is determined according to a voltage difference of the first voltage and the second voltage.

3. The package structure as defined in claim 1, wherein an electronic component is formed in the second carrier, and the electronic component comprises a resistance component or an inductance component.

4. The package structure as defined in claim 1, wherein a capacitance component is formed between the first interconnect structure and the first substrate.

5. The package structure as defined in claim 1, wherein the second carrier further comprises a second interconnect structure deposited on the first substrate, wherein the second interconnect structure and the first carrier are located on two opposite sides of the first substrate, and the first interconnect structure and the second interconnect structure are electrically isolated from each other.

6. The package structure as defined in claim 5, wherein a first pad on the first electronic device is electrically connected to the second interconnect structure through a first metal wire, wherein the package structure further comprises:
a third carrier, comprising:
a second substrate, in contact with the first carrier;
a third interconnect structure, electrically connected to a third voltage and formed on the second substrate, wherein the third interconnect structure and the first carrier are located on two opposite sides of the second substrate; and
a fourth interconnect structure, formed on the second substrate, wherein the fourth interconnect structure and the third interconnect structure are located on two opposite sides of the second substrate, wherein the fourth interconnect structure and the third interconnect structure are electrically isolated from each other; and
a second electronic device, deposited on the third interconnect structure and in contact with the third interconnect structure, wherein a second pad of the second electronic device is electrically connected to the first pad.

7. The package structure as defined in claim 6, wherein the second pad is electrically connected to the fourth interconnect structure through a second metal wire, and the fourth interconnect structure is electrically connected to the second interconnect structure through a third metal wire.

8. The package structure as defined in claim 6, wherein the second pad is electrically connected to the second interconnect structure through a second metal wire.

9. The package structure as defined in claim 6, wherein the third carrier further comprises:
a second insulating layer, deposited between the second substrate and the third interconnect structure and deposited between the second substrate and the fourth interconnect structure, wherein a thickness of the second insulating layer is determined according to a voltage difference of the first voltage and the third voltage and/or a voltage difference of the first carrier and the fourth interconnect structure.

10. The package structure as defined in claim 6, wherein the first substrate and the second substrate are in contact with each other to form a third substrate, wherein the third substrate is a semiconductor substrate.
